(19) United States
(12) Patent Application Publication
(10) Pub. No.: US 2024/0014635 A1
(43) Pub. Date: Jan. 11, 2024

(54) ATHERMAL WDM MULTISTRIPE ARRAYED WAVEGUIDE GRATING INTEGRATED-CAVITY LASER

(71) Applicant: The Regents of the University of California, Oakland, CA (US)

(72) Inventor: Sung-Joo Ben Yoo, Davis, CA (US)

(73) Assignee: The Regents of the University of California, Oakland, CA (US)

(21) Appl. No.: 18/040,625

(22) PCT Filed: Jun. 16, 2021
(86) PCT No.: PCT/US2021/037569

§ 371 Date: Feb. 3, 2023

Related U.S. Application Data
(60) Provisional application No. 63/040,262, filed on Jun. 17, 2020.

(51) Int. Cl. H01S 5/40; H01S 5/14; G02B 6/12; G02B 6/42

(52) U.S. Cl. CPC H01S 5/4087; H01S 5/141; H01S 5/4012; G02B 6/12019; G02B 6/4215

(57) ABSTRACT

The disclosed embodiments provide a system that implements a multiwavelength laser. This system includes a set of reflective semiconductor operational amplifiers (RSOAs) and a broadband loop mirror having an input and an output. The system also includes an arrayed waveguide grating (AWG) multiplexer having inputs that are coupled to outputs of the set of RSOAs, and having an output that feeds into the input of the loop mirror. During operation of the system, each RSOA in the set of RSOAs forms a wavelength-specific lasing cavity with a specific passband of the AWG multiplexer and the broadband loop mirror. The wavelength-specific laser signals produced by the wavelength-specific lasing cavities combine at the output of the loop mirror to produce a multiwavelength signal, which is emitted through an output of the system.

### CROSS-REFERENCE TO RELATED APPLICATIONS

This application claims priority under 35 U.S.C. § 119(e) to U.S. Provisional Application Ser. No. 63/040,262, entitled “Athermal Nanophotonic Lasers,” by inventor Sung-Joo Ben Yoo, filed on 17 Jun. 2020 (Attorney Docket No. UC18-295-2PSP), which is hereby incorporated herein by reference.

### FIELD

### Background

The disclosed embodiments generally relate to designs for semiconductor-based lasers. More specifically, the disclosed embodiments relate to the design of an athermal wavelength-division multiplexing (WDM) multistripe arrayed waveguide grating integrated-cavity (MAWGIC) laser.

### Related Art

In optical communication systems, wavelength-division multiplexing (WDM) can be used to greatly increase the communication capacity of optical fibers. The WDM technique involves multiplexing a number of wavelength-specific optical carrier signals onto a single optical fiber using different frequencies of laser light. In order to implement an AWG-based optical communication system, it is necessary to provide a multiwavelength laser that can be channeled into a single waveguide. To make such a system practical and cost-effective, the multiwavelength laser should ideally be integrated onto a semiconductor chip. It is also desirable for each of the multiple wavelengths to be athermal because if a wavelength drifts due to temperature variations, the performance of the associated optical carrier signal can be compromised.

Hence, what is needed is a design for an athermal laser, which can be cost-effectively integrated onto a semiconductor chip.

### SUMMARY

The disclosed embodiments provide a system that implements a multiwavelength laser. This system includes a set of reflective semiconductor operational amplifiers (RSOAs) and a broadband loop mirror having an input and an output. The system also includes an arrayed waveguide grating (AWG) multiplexer having inputs that are coupled to outputs of the set of RSOAs, and having an output that feeds into the input of the loop mirror. During operation of the system, each RSOA in the set of RSOAs forms a wavelength-specific lasing cavity with a specific passband of the AWG multiplexer and the broadband loop mirror. The wavelength-specific laser signals produced by the wavelength-specific lasing cavities combine at the output of the loop mirror to produce a multiwavelength signal, which is emitted through an output of the system.

In some embodiments, the AWG multiplexer comprises a reflective AWG, wherein signals travelling through arrayed waveguides in the AWG are reflected back through a single slab coupler.

In some embodiments, the AWG multiplexer is an athermal AWG multiplexer, which reduces wavelength drift caused by temperature variations.

In some embodiments, array arms of the athermal AWG have a composite silicon and silicon nitride structure, which provides an athermal reflective-AWG response.

In some embodiments, the system additionally includes a ring resonator coupled between the output of the AWG multiplexer and the input of the broadband loop mirror, wherein the ring resonator facilitates self-injection locking to provide additional bandpass filtering.

In some embodiments, the system additionally includes a ring resonator coupled between the output of the broadband loop mirror and the output of the multiwavelength laser, wherein the ring resonator facilitates self-injection locking to provide additional bandpass filtering.

In some embodiments, each RSOA in the set of RSOAs comprises a hybrid gain block coupled to an optical loop reflector.

In some embodiments, the broadband loop mirror comprises a Sagnac loop mirror.

In some embodiments, the output of the multiwavelength laser is coupled to a set of wavelength-specific optical transceivers.

In some embodiments, each wavelength-specific optical transceiver comprises: a wavelength-specific ring modulator for transmitting data on a wavelength-specific component of the multiwavelength signal produced by the multiwavelength laser; and a wavelength-specific ring-based add-drop filter for receiving data from a wavelength-specific component of a multiwavelength signal received from a remote source.

In some embodiments, the wavelength-specific ring modulator comprises an athermal InGaAsP/MOS/Si ring modulator, and the wavelength-specific ring-based add-drop filter comprises an athermal InGaAsP/MOS/Si ring resonator.

### BRIEF DESCRIPTION OF THE FIGURES

The patent or application file contains at least one drawing executed in color. Copies of this patent or patent application publication with color drawing(s) will be provided by the Office upon request and payment of the necessary fee.

FIG. 1 illustrates an exemplary multistripe array grating integrated-cavity (MAGIC) laser comprising an inverse-designed WDM multiplexer (MUX) and multiple nanolasers in an array in accordance with disclosed embodiments.

FIG. 2 illustrates an exemplary channel reflective AWG in accordance with disclosed embodiments.

FIG. 3A illustrates a set of RSOAs coupled to an arrayed waveguide grating (AWG) multiplexer in FIG. 3A in accordance with disclosed embodiments.

FIG. 3B illustrates an expanded portion of some of the array waveguides in the AWG multiplexer in accordance with disclosed embodiments.

FIG. 4A illustrates a configuration for a MAWGIC laser, wherein the AWG acts as a filter MUX and is coupled to a broadband reflector in accordance with disclosed embodiments.

FIG. 4B illustrates another configuration for a MAWGIC laser, which includes an additional ring filter, in accordance with disclosed embodiments.

FIG. 4C illustrates yet another configuration for a MAWGIC laser, which uses a ring resonator to provide injection locking, in accordance with disclosed embodiments.

FIG. 5A illustrates a unit cell for a wavelength-specific transceiver in accordance with the disclosed embodiments.

FIG. 5B illustrates a 20-wavelength WDM transceiver, which is associated with a core in a multi-core optical fiber in accordance with the disclosed embodiments.

FIG. 5C illustrates a semiconductor layout for a communication system that includes a WDM MAWGIC laser in accordance with the disclosed embodiments.

FIG. 6A presents a layout for an athermal ring modulator in accordance with the disclosed embodiments.

FIG. 6B provides a cross-sectional view of the athermal ring modulator illustrated in FIG. 6A in accordance with the disclosed embodiments.

FIG. 7 presents a flow chart illustrating a process for operating a WDM MAWGIC laser.

### DETAILED DESCRIPTION

The following description is presented to enable any person skilled in the art to make and use the present embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present embodiments. Thus, the present embodiments are not limited to the embodiments shown, but are to be accorded the widest scope consistent with the principles and features disclosed herein.

The data structures and code described in this detailed description are typically stored on a computer-readable storage medium, which may be any device or medium that can store code and/or data for use by a computer system. The computer-readable storage medium includes, but is not limited to, volatile memory, non-volatile memory, magnetic and optical storage devices such as disk drives, magnetic tape, CDs (compact discs), DVDs (digital versatile discs or digital video discs), or other media capable of storing computer-readable media now known or later developed.

The methods and processes described in the detailed description section can be embodied as code and/or data, which can be stored in a computer-readable storage medium as described above. When a computer system reads and executes the code and/or data stored on the computer-readable storage medium, the computer system performs the methods and processes embodied as data structures and code and stored within the computer-readable storage medium. Furthermore, the methods and processes described below can be included in hardware modules. For example, the hardware modules can include, but are not limited to, application-specific integrated circuit (ASIC) chips, field-programmable gate arrays (FPGAs), and other programmable-logic devices now known or later developed. When the hardware modules are activated, the hardware modules perform the methods and processes included within the hardware modules.

### Discussion

The disclosed embodiments relate to a new design for a multistripe arrayed waveguide grating integrated-cavity (MAWGIC) laser, which has athermal performance characteristics and can be cost-effectively integrated onto a semiconductor chip. This new design is motivated by a number of previous developments in semiconductor-based photonic technologies.

A number of researchers have investigated various designs for a multistripe array grating integrated-cavity (MAGIC) laser. (See J. B. D. Soole, K. Poguntke, A. Scherer, H. P. LeBlanc, C. Chang-Hasnain, J. R. Hayes, C. Caneau, R. Bhat, and M. A. Koza, “Multistripe array grating integrated cavity (MAGIC) laser: a new semiconductor laser for WDM applications,” Electronics Letters, vol. 28, pp. 1805-1807, 1992. Also, see K. R. Poguntke, J. B. D. Soole, A. Scherer, H. P. LeBlanc, C. Caneau, R. Bhat, and M. A. Koza, “Simultaneous multiple wavelength operation of a multistripe array grating integrated cavity laser,” Applied Physics Letters, vol. 62, pp. 2024-2026, 1993.)

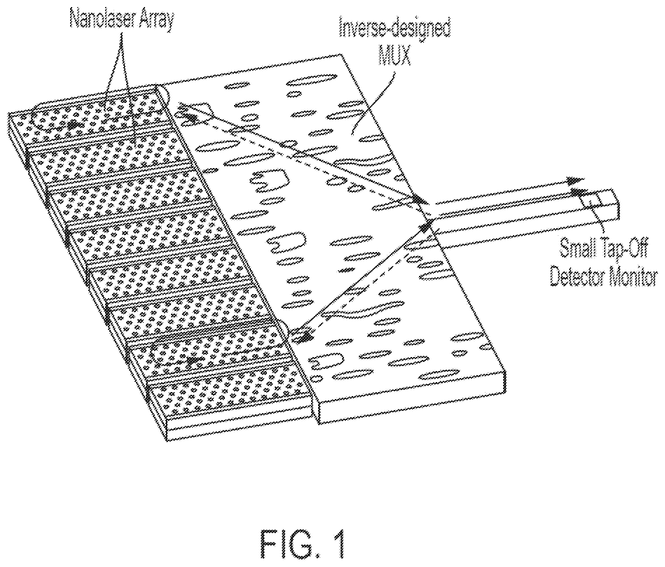

FIG. 1 illustrates an exemplary MAGIC laser comprised of an array of eight hybrid quantum dot nanolasers designed and fabricated for WDM wavelengths, which interfaces with an inverse-designed WDM multiplexer to form a MAGIC laser. The quantum dot nanolasers provide emission wavelengths, which are self-aligned with individual WDM MUX passbands. In one embodiment, the WDM wavelengths are centered at 1.180 μm, and span from 1.162 μm (258.2 THz) to 1.199 μm (250.2 THz). Note that both the inverse-designed-WDM multiplexers and the nanolasers can be designed and fabricated to be athermal. The fabrication accuracy of a 45 nm SPCLO process will provide accurate wavelength registration within the 800 GHz band (for 10 data channels plus one clock channel) for the lasers and the WDM multiplexers. As illustrated in FIG. 1, a small “tap-off detector” can be used to monitor the wavelength registration of each laser at system startup and while monitoring system operation. While a coarse WDM grid at 800 GHz and 45 nm processing should provide relatively accurate alignments of the lasers and the WDM multiplexer passbands, static tuning of ˜2 nm can be achieved on each laser by utilizing MOS or SIS capacitor semiconductor (GaAs)-oxidesilicon at the bonding interface between the laser and the silicon device layer since each of the p and n contacts on the lasers is independent. In this case, the nanolaser array will lock its wavelengths by electro-optically tuning the semiconductor-insulator-semiconductor capacitive tuning of the voltage between the p-type silicon (ground) and the n⁺⁺ contact on the nanolaser. Once the calibration is done, the drift will be negligible due to the athermal nature of the laser, the WDM demultiplexer, and the resonator.

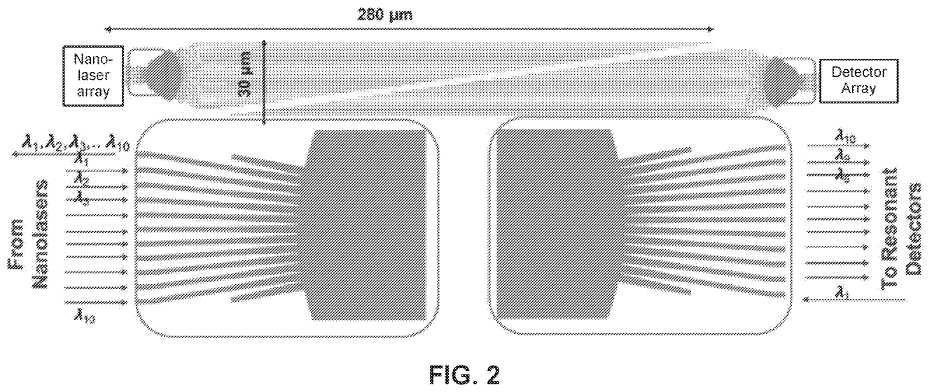

In another development, reflective AWGs implemented on silicon photonics have proven to provide a very compact implementation and also low crosstalk (below −25 dB). (See L. G. de Peralta, A. A. Bernussi, S. Frisbie, R. Gale, and H. Temkin, “Reflective arrayed waveguide grating multiplexer,” IEEE Photonics Technology Letters, vol. 15, pp. 1398-1400, 2003.) FIG. 2 illustrates an exemplary layout for a 10 channel reflective AWG.

Note that such reflective AWGs, which provide both multiplexing and demultiplexing functionality, can be used to replace the inverse-designed WDM multiplexer in the MAGIC laser to form a new type of WDM laser that we refer to as a WDM “multistripe arrayed waveguide grating integrated-cavity” (MAWGIC) laser, which can be fabricated through a wafer bonding process.

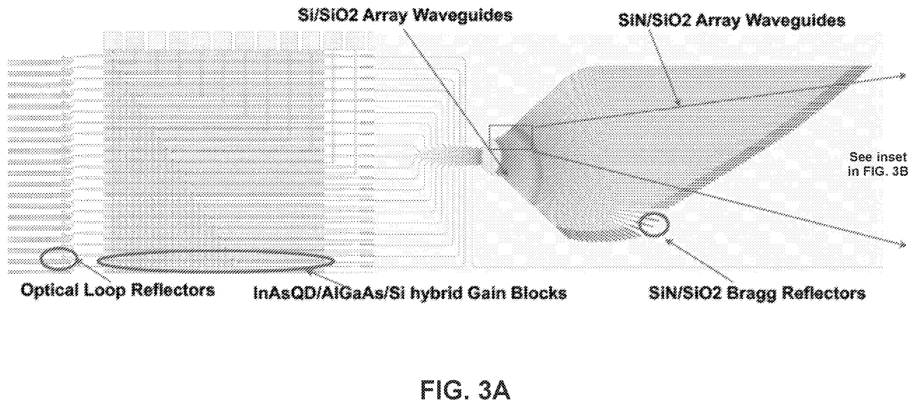

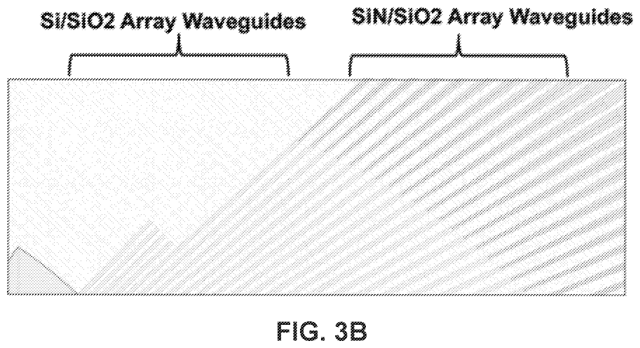

FIG. 3A illustrates an exemplary semiconductor layout for a portion of a WDM MAWGIC laser that includes an athermal AWG multiplexer comprised of array waveguides and Bragg reflectors (on the right-hand side of FIG. 3A), which is coupled to an array of RSOAs comprised of hybrid gain blocks and optical loop reflectors (on the left-hand side of FIG. 3A). As illustrated in the inset that appears in FIG. 3B, the athermal reflective-AWG response is provided by the composite structure of the compact reflective-arrayed waveguide gratings (RAWGs) through the interplay between the silicon part of the waveguides with thermal optic coefficient (TOC): 1.976e−4/K, and the silicon nitride part of the waveguides with TOC=1.57e−5/K, so that the different length ratios in each of the array waveguides will achieve athermal AWG operation by structural design. (For additional details, see U.S. patent application Ser. No. 12/899,715, entitled “Athermal Silicon Photonics Array Waveguide Grating (AWG) Employing Different Core Geometries in the Array Waveguides,” by inventor Katsunari Okamoto, filed 7 Oct. 2010.) The single axial mode operation for each laser is also enforced by engineering a narrow coupling region of the arrayed waveguide arms so that only one mode achieves lower than 1 dB intracavity loss.

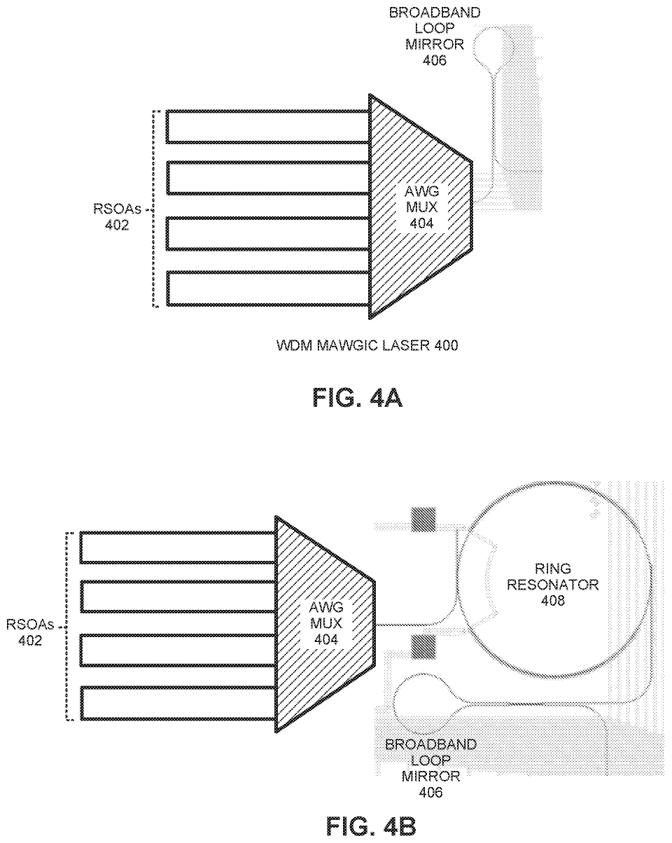

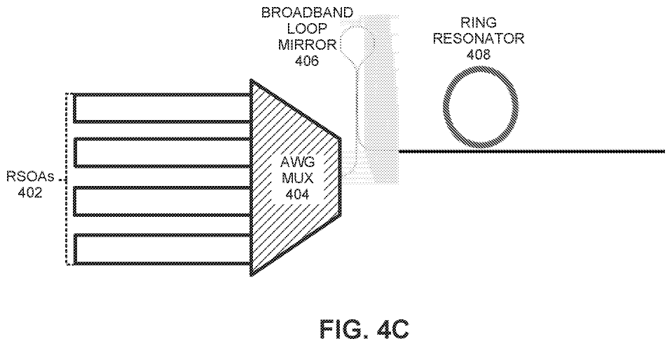

The AWG multiplexer and RSOAs illustrated in FIG. 3A can be integrated with a broadband loop mirror (reflector) to form a WDM MAWGIC laser. For example, FIG. 4A provides a high-level diagram illustrating a set of RSOAs 402, which are integrated with an AWG multiplexer 404 and a broadband loop mirror 406 to form WDM MAWGIC laser 400.

During operation of WDM MAWGIC laser 400, each RSOA in the set of RSOAs 402 forms a wavelength-specific lasing cavity with a specific passband of the AWG multiplexer 404 and the broadband loop mirror 406. The wavelength-specific laser signals produced by the wavelength-specific lasing cavities combine at the output of the loop mirror 406 to produce a multiwavelength laser output. Note that the light blue lines illustrated in FIG. 4A are electrodes. By tuning these electrodes, which are comprised of nickel phosphate and are athermal and CMOS-compatible, it is possible to tune the wavelength of the associated lasing cavity.

FIG. 4B illustrates an alternative embodiment of the WDM MAWGIC laser, which additionally includes a ring resonator 408 coupled between the output of the AWG multiplexer 404 and the broadband loop mirror 406, wherein the ring resonator 408 facilitates self-injection locking to provide additional bandpass filtering.

FIG. 4C illustrates yet another embodiment of the WDM MAWGIC laser, which includes a ring resonator 408 coupled between the broadband loop mirror 406 and the output of the multiwavelength laser, wherein the ring resonator 408 also facilitates self-injection locking to provide additional bandpass filtering.

### Transceiver System

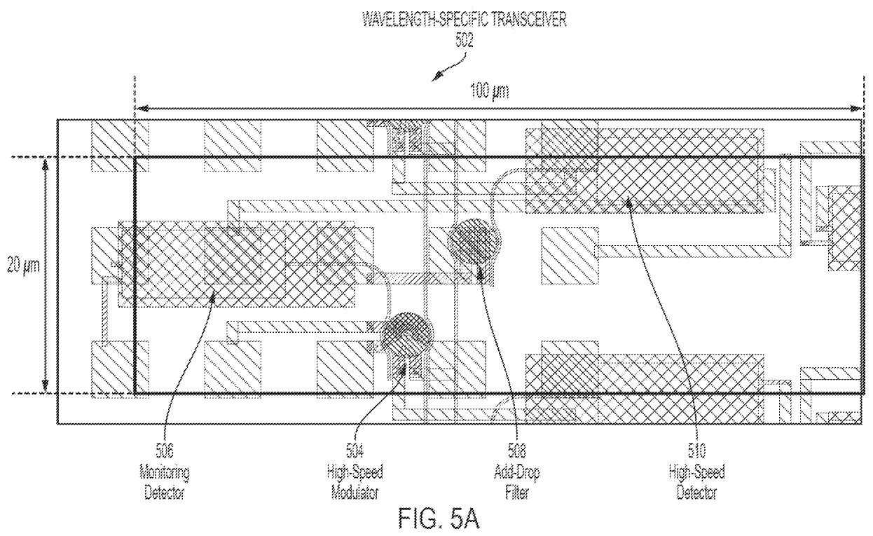

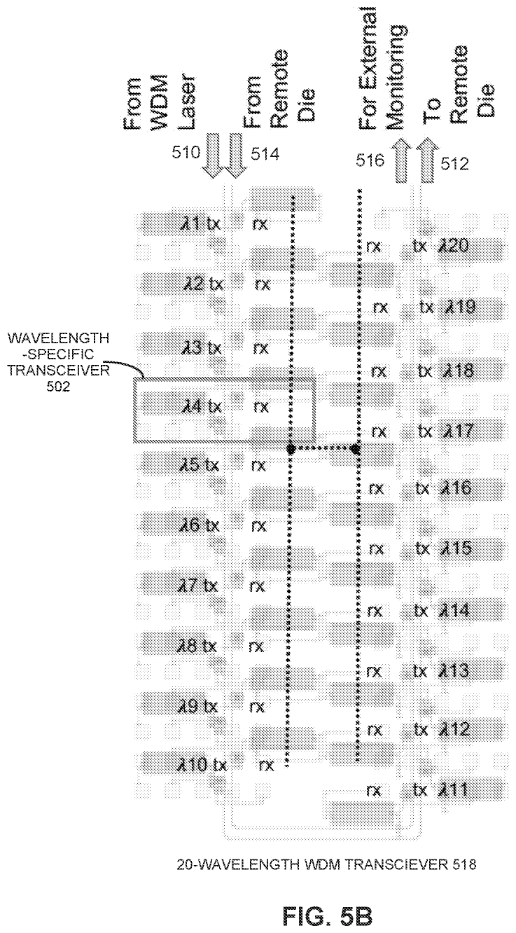

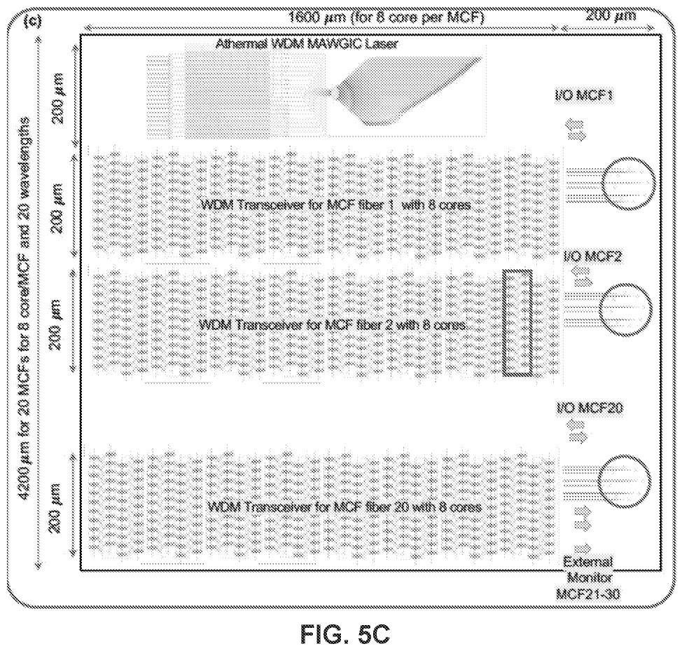

The above-described athermal WDM MAWGIC laser can be used to provide wavelength-specific carrier signals for a set of optical transceivers in an optical communication system. For example, FIG. 5A illustrates a layout of a unit cell for a wavelength-specific optical transceiver 502. More specifically, this layout illustrates a 20 μm×100 μm unit cell, which includes an athermal MOS high-speed modulator 504 with a monitoring detector 506, and an athermal wavelength add-drop filter 508 with a high-speed detector 510 (nano-photoreceiver).

As illustrated in FIG. 5B, a set of such wavelength-specific transceivers can be combined to produce a 20-wavelength WDM transceiver 518 for one of the cores on a multi-core-fiber, wherein each transceiver is optimized for a specific wavelength. This 20-wavelength WDM transceiver 518 is coupled to the output 510 of a WDM MAWGIC laser to form an outgoing optical signal 512, and is coupled to an incoming optical signal from a remote source (die) 514 and an output 516 for external monitoring (optional). The black dotted lines indicate the clock distribution from electronic receivers receiving clock signals on wavelength λ₅, which is distributed to other receivers.

Note that a single WDM MAWGIC laser can be coupled to multiple multicore fibers. For example, FIG. 5C presents a conceptual layout for a 40 Tb/s duplex I/O die with twenty 8-core MCF fibers and a single athermal MAWGIC laser.

The optical communication system illustrated in FIGS. 5A-5C can achieve 91 fJ/b on an athermal platform that provides: 20 wavelengths, on-off-keying (optionally DQPSK), 8 cores per fiber, to provide a 20 fiber system at 25 GS/s (26.3 GS/s on 19 wavelengths plus one clock wavelength) reaching 40 Tb/s duplex (40 Tb/s outbound and 40 Tb/s inbound). This can be implemented on a 2200 μm×1600 μm die with athermal performance achieving 18.2 Tb/s/mm edge density achieving robust operation across 0-100° C. without temperature control. Optionally, we also propose a DQPSK scheme that combines I and Q modulation/demodulation, at 0.20 pJ/b at 16 Tb/s/mm utilizing 10 wavelengths with the same athermal performance.

### Athermal Ring Modulators and Add-Drop Filter

In order to operate properly, the athermal transceiver 518 described above requires an athermal modulator 504 and an athermal add-drop filter 508. The inventors have successfully demonstrated athermal ring modulators at both C-band and O-band. (See [Feng 2015] S. Feng, K. Shang, J. T. Bovington, R. Wu, B. Guan, K.-T. Cheng, J. E. Bowers, and S. J. Ben Yoo, “Athermal silicon ring resonators clad with titanium dioxide for 1.3 micron wavelength operation,” Opt. Express, vol. 23, no. 20, pp. 25653-25660, 2015, doi: 10.1364/OE.23.025653.) Also, recent demonstrations have shown that InGaAsP/MOS/Si capacitive Mach-Zehnder modulates with extremely high modulation efficiency (V_{π}·L=0.047 V-cm) compared to standard silicon photonic modulators (V_{π}·L˜1 V-cm).

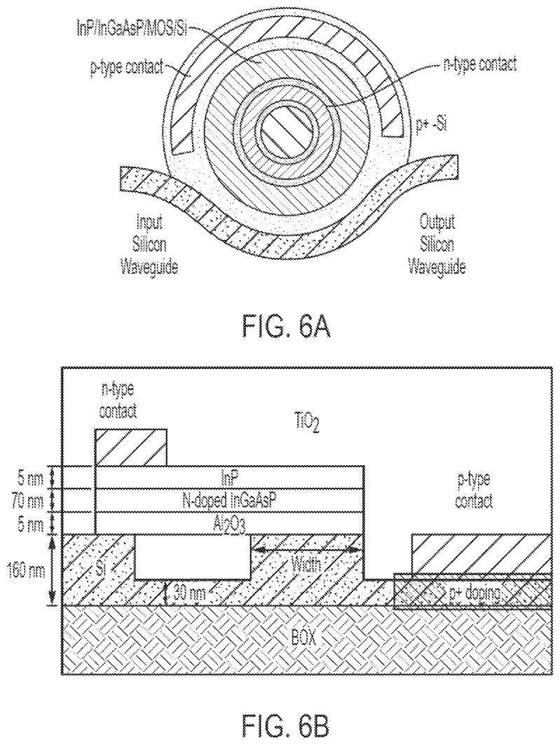

FIG. 6A presents a layout for an exemplary athermal n-InP/InGaAsP/MOS/Si ring modulator and FIG. 6B illustrates a corresponding cross-sectional view of the ring modulator. Empirical results indicate that this type of athermal InGaAsP/MOS/Si modulator can achieve Vₚₚ=0.50 V of insertion loss (IL) 0.3 dB and extinction (ER) at >8 dB (while a non-athermal version achieves Vₚₚ=0.25V). As noted in our athermal silicon photonic results in [Feng 2015], there is a bowing effect due to the higher order TOC and confinement effects, which can be corrected by DC voltage tuning on the capacitive MOS device. Hence, a single pair of p-type and n-type CMOS-compatible (Ni₂P) contacts can achieve both wavelength tuning/locking and high-speed modulation. The athermal design allows this DC tuning to be no higher than 1.5 V to support the necessary tuning. Also, the proposed MOS modulators have 20 different diameter designs. Moreover, at the MOS capacitance of 0.3 μF/cm², the athermal MOS modulator exhibits <20 fF capacitance.

### Process for Operating a WDM MAWGIC Laser

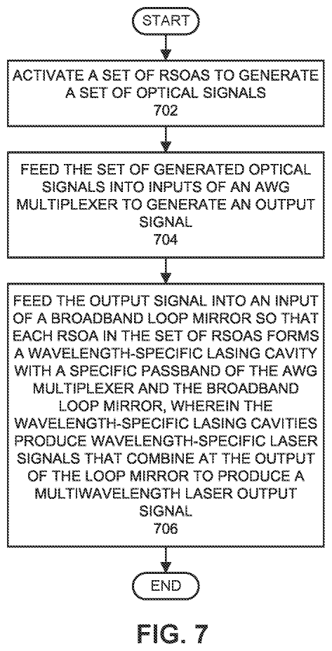

FIG. 7 presents a flow chart illustrating the process for operating a WDM MAWGIC laser. During operation, the system first activates a set of RSOAs to generate a set of optical signals (step 702). Next, the system feeds the set of generated optical signals into inputs of an AWG multiplexer to generate an output signal (step 704). The system then feeds the output signal into an input of a broadband loop mirror so that each RSOA in the set of RSOAs forms a wavelength-specific lasing cavity with a specific passband of the AWG multiplexer and the broadband loop mirror, wherein the wavelength-specific lasing cavities produce wavelength-specific laser signals that combine at the output of the loop mirror to produce a multiwavelength laser output signal (step 706).

Various modifications to the disclosed embodiments will be readily apparent to those skilled in the art, and the general principles defined herein may be applied to other embodiments and applications without departing from the spirit and scope of the present invention. Thus, the present invention is not limited to the embodiments shown, but is to be accorded the widest scope consistent with the principles and features disclosed herein.

The foregoing descriptions of embodiments have been presented for purposes of illustration and description only. They are not intended to be exhaustive or to limit the present description to the forms disclosed. Accordingly, many modifications and variations will be apparent to practitioners skilled in the art. Additionally, the above disclosure is not intended to limit the present description. The scope of the present description is defined by the appended claims.

What is claimed is:

1. A multiwavelength laser, comprising:
a set of reflective semiconductor operational amplifiers (RSOAs);
a broadband loop mirror having an input and an output; and
an arrayed waveguide grating (AWG) multiplexer having inputs that are coupled to outputs of the set of RSOAs, and having an output that feeds into the input of the loop mirror;
wherein each RSOA in the set of RSOAs forms a wavelength-specific lasing cavity with a specific passband of the AWG multiplexer and the broadband loop mirror; and
wherein wavelength-specific laser signals produced by the wavelength-specific lasing cavities combine at the output of the loop mirror to produce a multiwavelength signal, which is emitted through an output of the multiwavelength laser.

2. The multiwavelength laser of claim 1, wherein the AWG multiplexer comprises a reflective AWG, wherein signals travelling through arrayed waveguides in the AWG are reflected back through a single slab coupler.

3. The multiwavelength laser of claim 2, wherein the AWG multiplexer is an athermal AWG multiplexer, which reduces wavelength drift caused by temperature variations.

4. The multiwavelength laser of claim 3, wherein array arms of the athermal AWG have a composite silicon and silicon nitride structure, which provides an athermal reflective-AWG response.

5. The multiwavelength laser of claim 1, further comprising a ring resonator coupled between the output of the AWG multiplexer and the input of the broadband loop mirror, wherein the ring resonator facilitates self-injection locking to provide additional bandpass filtering.

6. The multiwavelength laser of claim 1, further comprising a ring resonator coupled between the output of the broadband loop mirror and the output of the multiwavelength laser, wherein the ring resonator facilitates self-injection locking to provide additional bandpass filtering.

7. The multiwavelength laser of claim 1, wherein each RSOA in the set of RSOAs comprises a hybrid gain block coupled to an optical loop reflector.

8. The multiwavelength laser of claim 1, wherein the broadband loop mirror comprises a Sagnac loop mirror.

9. The multiwavelength laser of claim 1, wherein the output of the multiwavelength laser is coupled to a set of wavelength-specific optical transceivers.

10. The multiwavelength laser of claim 9, wherein each wavelength-specific optical transceiver in the set of wavelength-specific optical transceivers comprises:
a wavelength-specific ring modulator for transmitting data on a wavelength-specific component of the multiwavelength signal produced by the multiwavelength laser; and
a wavelength-specific ring-based add-drop filter for receiving data from a wavelength-specific component of a multiwavelength signal received from a remote source.

11. The multiwavelength laser of claim 10,
wherein the wavelength-specific ring modulator comprises an athermal InGaAsP/MOS/Si ring modulator; and
wherein the wavelength-specific ring-based add-drop filter comprises an athermal InGaAsP/MOS/Si ring resonator.

12. An optical communication system, comprising:
an inbound optical channel, which carries an inbound multiwavelength optical signal received from a remote transmitter;
an outbound optical channel, which carries an outbound multiwavelength optical signal to be transmitted to a remote receiver;
a set of wavelength-specific optical transceivers, which are coupled to the inbound optical channel and the output optical channel, wherein each of the wavelength-specific optical transceivers comprises:
a wavelength-specific ring modulator for transmitting data on a wavelength-specific component of the outbound multiwavelength optical signal carried by the outbound optical channel; and
a wavelength-specific ring-based add-drop filter for receiving data from a wavelength-specific component of the inbound multiwavelength optical signal carried by the inbound optical channel; and
a wavelength division multiplexing (WDM) microstripe arrayed waveguide grating integrated-cavity (MAWGIC) laser that generates the outbound multiwavelength optical signal, which feeds into the outbound optical channel.

13. The optical communication system of claim 12, wherein the WDM MAWGIC laser comprises:
a set of reflective semiconductor operational amplifiers (RSOAs);
a broadband loop mirror having an input and an output; and
an arrayed waveguide grating (AWG) multiplexer having inputs that are coupled to outputs of the set of RSOAs, and having an output that feeds into the input of the loop mirror;
wherein each RSOA in the set of RSOAs forms a wavelength-specific lasing cavity with a specific passband of the AWG multiplexer and the broadband loop mirror; and
wherein wavelength-specific laser signals produced by the wavelength-specific lasing cavities combine at the output of the loop mirror to produce a multiwavelength signal, which is emitted through an output of the WDM MAWGIC laser.

14. The optical communication system of claim 13, wherein the AWG multiplexer comprises a reflective AWG, wherein signals travelling through arrayed waveguides in the AWG are reflected back through a single slab coupler.

15. The optical communication system of claim 14, wherein the AWG multiplexer is an athermal AWG multiplexer, which reduces wavelength drift caused by temperature variations.

16. The optical communication system of claim 15, wherein array arms of the athermal AWG have a composite silicon and silicon nitride structure, which provides an athermal reflective-AWG response.

17. The optical communication system of claim 13, further comprising a ring resonator coupled between the output of the AWG multiplexer and the input of the broadband loop mirror, wherein the ring resonator facilitates self-injection locking to provide additional bandpass filtering.

18. The optical communication system of claim 13, further comprising a ring resonator coupled between the output of the broadband loop mirror and the output of the multiwavelength laser, wherein the ring resonator facilitates self-injection locking to provide additional bandpass filtering.

19. The optical communication system of claim 13, wherein each RSOA in the set of RSOAs comprises a hybrid gain block coupled to an optical loop reflector.

20. The optical communication system of claim 13, wherein the broadband loop mirror comprises a Sagnac loop mirror.

21. The optical communication system of claim 12,
wherein the wavelength-specific ring modulator within each wavelength-specific optical transceiver in the set of wavelength-specific optical transceivers comprises an athermal InGaAsP/MOS/Si ring modulator; and
wherein the wavelength-specific ring-based add-drop filter within each wavelength-specific optical transceiver in the set of wavelength-specific optical transceivers comprises an athermal InGaAsP/MOS/Si ring resonator.

22. A method for operating a multiwavelength laser, comprising:
activating a set of reflective semiconductor operational amplifiers (RSOAs) to generate a set of optical signals;
feeding the set of generated optical signals into inputs of an arrayed waveguide grating (AWG) multiplexer to generate an output signal; and
feeding the output signal into an input of a broadband loop mirror so that each RSOA in the set of RSOAs forms a wavelength-specific lasing cavity with a specific passband of the AWG multiplexer and the broadband loop mirror;
wherein the wavelength-specific lasing cavities produce wavelength-specific laser signals that combine at the output of the loop mirror to produce a multiwavelength laser output signal.

23. The method of claim 22, wherein the AWG multiplexer comprises a reflective AWG, wherein signals travelling through arrayed waveguides in the AWG are reflected back through a single slab coupler.

24. The method of claim 23, wherein the AWG multiplexer is an athermal AWG multiplexer, which reduces wavelength drift caused by temperature variations.

25. The method of claim 22, wherein the method further comprises using a ring resonator coupled between the output of the AWG multiplexer and the input of the broadband loop mirror to provide additional bandpass filtering based on self-injection locking.

26. The method of claim 22, wherein the method further comprises using a ring resonator coupled between the output of the broadband loop mirror and the output of the multiwavelength laser to provide additional bandpass filtering based on self-injection locking.

27. The method of claim 1, wherein the method further comprises coupling the output of the multiwavelength laser to a set of wavelength-specific optical transceivers to facilitate optical communications, wherein each of the wavelength-specific optical transceivers comprises:
an athermal wavelength-specific ring modulator for transmitting data on a wavelength-specific component of the multiwavelength signal produced by the multiwavelength laser; and
an athermal wavelength-specific ring-based add-drop filter for receiving data from a wavelength-specific component of a multiwavelength signal received from a remote source.
